(19) United States
(12) Patent Application Publication
(10) Pub. No.: US 2014/0287670 A1
(43) Pub. Date: Sep. 25, 2014

(54) CONTAINER DATA CENTER

(71) Applicant: HON HAI PRECISION INDUSTRY CO., LTD., New Taipei (TW)

(72) Inventor: TAI-WEI LIN, New Taipei (TW)

(73) Assignee: HON HAI PRECISION INDUSTRY CO., LTD., New Taipei (TW)

(21) Appl. No.: 13/867,111

(22) Filed: Apr. 21, 2013

(30) Foreign Application Priority Data
Mar. 22, 2013 (TW) 102110153

(51) Int. Cl. H05K 5/02

(52) U.S. Cl. CPC H05K 5/0213
USPC 454/184; 454/284

(57) ABSTRACT

An air guiding device includes two opposite first air guiding apparatus and a second air guiding apparatus mounted on tops of the first air guiding apparatus. Each first air guiding apparatus includes a stretchable first guiding piece. The second air guiding apparatus includes a stretchable second guiding piece. Distal ends of the first and second air guiding pieces are pulled out toward the same direction, the first and second guiding pieces cooperatively bound an airflow channel.

### BACKGROUND

1. Technical Field

The present disclosure relates to the cooling of container data centers and, particularly, to a container data center with an air guiding device for guiding airflow.

2. Description of Related Art

In a warehouse computing facility, a plurality of container data centers can be stored in the room for data centralization. Each container data center includes a container and a plurality of cabinets received in the container. Each cabinet includes a plurality of servers generating a great amount of heat during operation. The heat needs to be dissipated timely to ensure the proper functioning of the container data centers. Conventionally, the room includes a sidewall defining a plurality of openings. An end wall of each container defines an air inlet facing the openings of the room, and an air duct is arranged between the air inlet of each container and the corresponding opening of the room for guiding air. Air enters the room through the openings and the air ducts, and flows into the containers through the air inlets, to cool the servers of the cabinets. However, the air ducts are integrally formed, and are mounted to the containers through screws, so it is inconvenient to install or uninstall the air ducts to or from the containers.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a container data center, wherein the container data center includes two first air guiding apparatus and a second air guiding apparatus.

FIG. 2 is an exploded, isometric view of one of the first air guiding apparatus of FIG. 1.

FIG. 3 is an enlarged view of the second air guiding apparatus of FIG. 1.

FIG. 4 is an assembled, isometric view of FIG. 1.

FIG. 5 is similar to FIG. 4, but showing the container data center in use.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

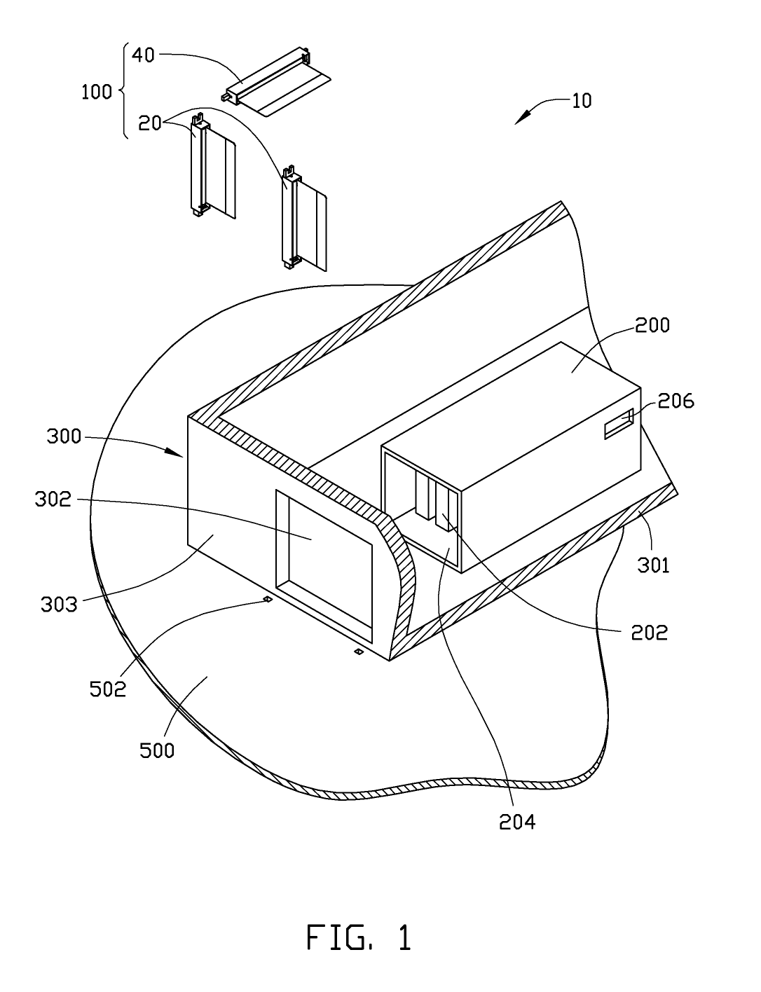

FIG. 1 shows an exemplary embodiment of a container data center 10. The container data center 10 includes a container 200 received in a room 300, and an air guiding device 100.

A plurality of cabinets 202 is received in the container 200. The container 200 defines an air inlet 204 in an end wall of the container 200, and an air outlet 206 in a sidewall of the container 200 away from the air inlet 204. The room 300 is supported on a floor 500. The room 300 includes a bottom wall 301 and a sidewall 303 perpendicularly extending up from a side of the bottom wall 301. The sidewall 303 defines a rectangular through hole 302 facing and aligning with the air inlet 204 of the container 200. The floor 500 defines two spaced latching holes 502 adjacent to two opposite sides of the through hole 302.

The air guiding device 100 includes two first air guiding apparatus 20 and a second air guiding apparatus 40.

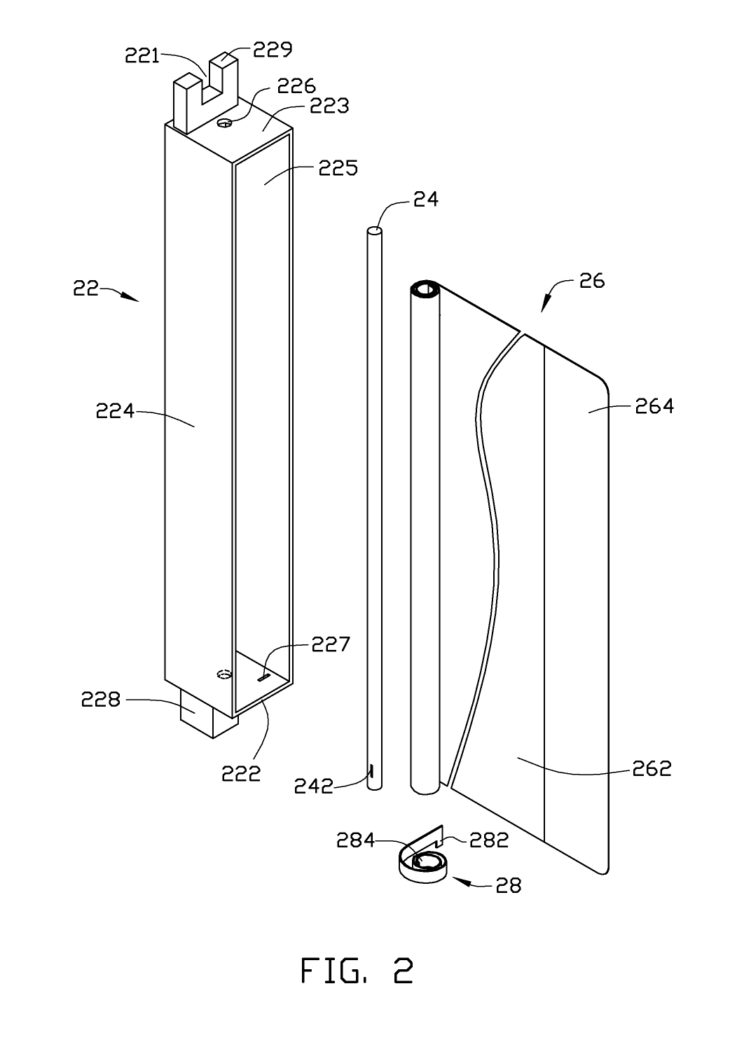

FIG. 2 shows one of the first air guiding apparatus 20. The first air guiding apparatus 20 includes a bracket 22, a shaft 24, a flexible first air guiding member 26, and a resilient member 28.

The bracket 22 includes a rectangular bottom plate 222, a top plate 223 opposite to the bottom plate 222, and two side plates 224 perpendicularly connected between sides of the top plate 223 and the bottom plate 222. The bottom plate 222, the top plate 223, and the side plates 224 cooperatively bound a receiving space 225. The bottom plate 222 and the top plate 223 define two opposite shaft holes 226. The bottom plate 222 defines a latching hole 227 adjacent to the shaft hole 226. A position block 228 extends down from the bottom plate 222. A connecting block 229 extends up from the top plate 223, and the connecting block 229 defines a cutout 221 aligning with the shaft hole 226.

Two opposite ends of the shaft 24 are rotatably inserted in the shaft holes 226. The circumference of one of the ends of the shaft 24 longitudinally defines a long positioning hole 242.

The first air guiding member 26 includes a rectangular guiding piece 262 and a position portion 264 mounted to a first end of the guiding piece 262. The guiding piece 262 is made of flexible material, such as pliable plastic. In the embodiment, the position portion 264 is a bar-shaped magnet.

The resilient member 28 is a clockwork spring, and includes a first positioning end 282 at an outer side of the resilient member 28, and a second positioning end 284 at an inner side of the resilient member 28.

In assembling each first air guiding apparatus 20, a second end of the guiding piece 262 opposite to the position portion 264 is fixed to the shaft 24. The shaft 24 is rotated to reel the guiding piece 262 about the shaft 24. The resilient member 28 is fitted about the end of the shaft 24 defining the positioning hole 242. The second end 284 of the resilient member 28 is latched in the positioning hole 242 of the shaft 24. A combination of the shaft 24, the guiding piece 262, and the resilient member 28 is received in the receiving space 225 of the bracket 22. The ends of the shaft 24 are rotatably inserted in the shaft holes 226 of the bracket 22. The first position end 282 of the resilient member 28 is latched in the latching hole 227 of the bracket 22. The position portion 264 extends out of the receiving space 225. The air guiding piece 262 can be wound on or let out from the shaft 24 when the shaft 24 rotates. The resilient member 28 biases the air guiding piece 262 to be reeled on the shaft 24.

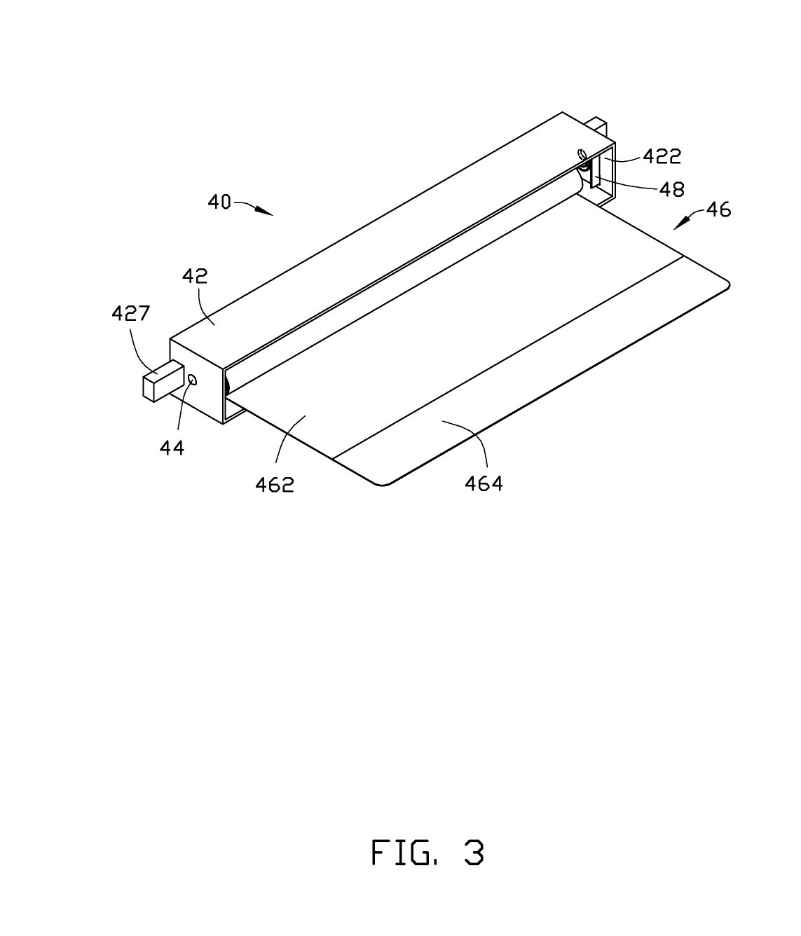

FIG. 3 shows the second air guiding apparatus 40. The second air guiding apparatus 40 is substantially similar to the first air guiding apparatus 20. The second air guiding apparatus 40 includes a bracket 42 defining a receiving space 422, a shaft 44 rotatably installed to the bracket 42 and received in the receiving space 422, a second air guiding member 46, and a resilient member 48 connected between the shaft 44 and the bracket 42. The second air guiding member 46 includes a guiding piece 462 reeled about the shaft 44, and a position portion 464 mounted to an end of the guiding piece 462 and extending out of the receiving space 442. The resilient member 48 can bias the guiding piece 462 to be reeled on the shaft 44. Two connecting poles 427 protrude out from two opposite ends of the bracket 42. In the embodiment, the position portion 464 is a bar-shaped magnet.

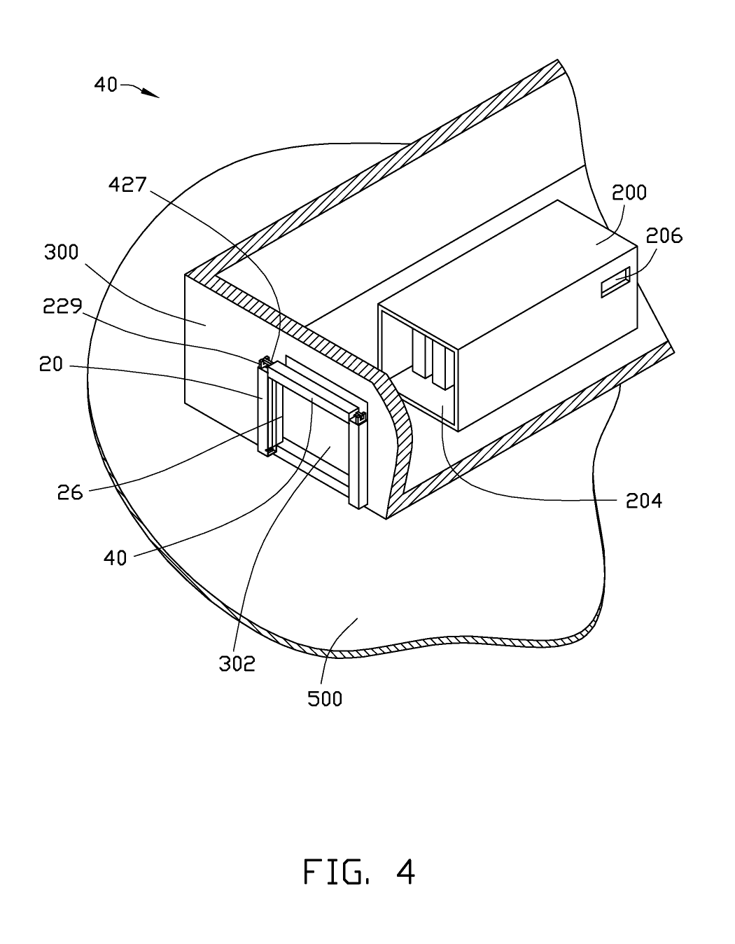

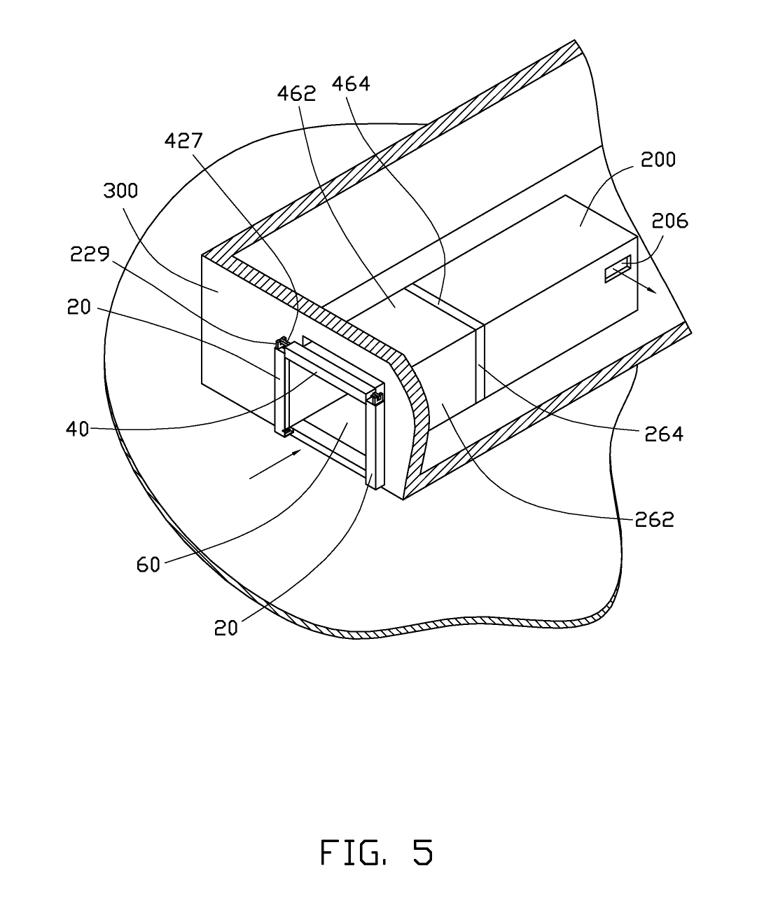

FIG. 4 and FIG. 5 show that in use, the position blocks 228 of the first guiding apparatus 20 are inserted into the latching holes 502 of the floor 500, to allow the position portions 264 of the first guiding apparatus 20 to face the two sides of the through hole 302, and the cutouts 221 of the brackets 22 are aligned with each other. The connecting poles 427 of the second air guiding apparatus 40 are inserted into the cutouts 221 of the first guiding apparatus 20. The bracket 42 of the second air guiding apparatus 40 is sandwiched between the brackets 22 of the first air guiding apparatus 20. The position portion 464 of the second air guiding apparatus 40 faces a top side of the through hole 302.

The position portions 264 and 464 of the guiding pieces 262 and 462 are pulled toward the through hole 302. The shafts 24 and 44 are rotated, thereby deforming the resilient members 28 and 48. The position portions 264 and 464 are extended through the through hole 302, toward the air inlet 204 of the container 200, and are attracted by two sidewalls and a top wall of the container 200. Thus, the guiding pieces 262 and 462 cooperatively bound an airflow channel 60 communicating with the air inlet 204 of the container 200. Air outside the room 300 flows through the airflow channel 60, and the air inlet 204, and enters the container 200. Most of the heat generated in the cabinets 202 is dissipated out of the container 200 through the air outlet 206.

When the air guiding device 100 is not in use, the position portions 264 and 464 are disengaged from the sidewalls and the top wall of the container 200. The resilient members 28 and 48 are restored to bias the shafts 24 and 44 to rotate, and the guiding pieces 262 and 462 are reeled back on the shafts 24 and 44 in the receiving spaces 225 and 422 of the brackets 22 and 42.

In another embodiment, the position portions 264 and 464 are hooks for latching with the container 200.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An air guiding device, comprising:
two opposite first air guiding apparatus each comprising a stretchable first guiding piece; and
a second air guiding apparatus mounted on tops of the first air guiding apparatus, wherein the second air guiding apparatus comprises a stretchable second guiding piece, ends of the first and second air guiding pieces are operable of being stretched out toward a same direction, to cooperatively bound an airflow channel.

2. The air guiding device of claim 1, wherein each first air guiding apparatus further comprises a bracket defining a receiving space, and a shaft rotatably installed to the bracket and received in the receiving space, the first guiding piece is reeled about the shaft.

3. The air guiding device of claim 2, wherein the first guiding piece of each first air guiding apparatus comprises a first end mounted to the shaft, and a position portion mounted to a second end of the guiding piece.

4. The air guiding device of claim 3, wherein the position portion is a magnet.

5. The air guiding device of claim 2, wherein the bracket comprises a bottom plate, a top plate opposite to the bottom plate, and two side plates connected between the top plate and the bottom plate, the receiving space is bounded by the bottom plate, the top plate, and the side plates.

6. The air guiding device of claim 5, wherein the bottom plate and the top plate define two opposite shaft holes, two ends of the shaft are rotatably inserted into the shaft holes of the bracket.

7. The air guiding device of claim 5, wherein two connecting blocks extend up from the top plates of the first air guiding apparatus, the second air guiding apparatus is mounted between the connecting blocks.

8. The air guiding device of claim 2, wherein each first air guiding apparatus further comprises a resilient member installed between the bracket and the shaft, the resilient member biases the first guiding piece to be reeled back on the shaft.

9. The air guiding device of claim 1, wherein the second air guiding apparatus further comprises a bracket defining a receiving space, a shaft rotatably installed to the bracket and received in the receiving space, and a resilient member connected between the bracket and the shaft, the second guiding piece is reeled about the shaft, the resilient member biases the second guiding piece to being reeled back on the shaft.

10. The air guiding device of claim 9, wherein the second guiding piece comprises a first end mounted to the shaft, and a position portion mounted to a second end of the first guiding piece.

11. The air guiding device of claim 9, wherein the position portion is a magnet.

12. A container data center, comprising:
a room comprising a sidewall defining a through hole;
a container received in the room, the container defines an air inlet facing and aligning with the through hole of the room; and
an air guiding device comprising two first air guiding apparatus mounted to the sidewall of the room and located at two opposite sides of the through hole, and a second air guiding apparatus mounted on tops of the first air guiding apparatus;
wherein each first air guiding apparatus comprises a stretchable first guiding piece, a distal end of the first guiding piece is operable of being pulled out and extended through the through hole, to be mounted to the container, the second air guiding apparatus comprises a stretchable second guiding piece, a distal end of the second guiding piece is operable of being pulled out and extended through the through hole, to be mounted to the container, the first and second guiding pieces cooperatively bound an airflow channel communicating with the air inlet of the container and the through hole of the room.

13. The container data center of claim 12, wherein each first air guiding apparatus further comprises a bracket defining a receiving space, a shaft rotatably installed to the bracket and received in the receiving space, the first guiding piece is reeled about the shaft.

14. The container data center of claim 13, wherein the first guiding piece comprises a first end mounted to the shaft, and a position portion mounted to a second end of the guiding piece.

15. The container data center of claim 13, wherein the bracket comprises a bottom plate, a top plate opposite to the bottom plate, and two side plates connected between the top plate and the bottom plate, the receiving space is bounded by the bottom plate, the top plate, and the side plates.

16. The container data center of claim 15, wherein the bottom plate and the top plate define two opposite shaft holes, two ends of the shaft are rotatably inserted into the shaft holes of the bracket.

17. The container data center of claim 15, wherein two connecting blocks extend up from the top plates of the first air guiding apparatus, the second air guiding apparatus is mounted between the connecting blocks.

18. The container data center of claim 13, wherein each first air guiding apparatus further comprises a resilient member installed between the bracket and the shaft, the resilient member biases the first guiding piece to be reeled on the shaft.

19. The container data center of claim 12, wherein the second air guiding apparatus further comprises a bracket defining a receiving space, a shaft rotatably installed to the bracket and received in the receiving space, and a resilient member connected between the bracket and the shaft, the second guiding piece is reeled about the shaft, the resilient member biases the second guiding piece to be reeled on the shaft.

20. The container data center of claim 19, wherein the second guiding piece comprises a first end mounted to the shaft, and a position portion mounted to a second end of the first guiding piece.
